(19) United States
(12) Patent Application Publication
(10) Pub. No.: US 2012/0180844 A1
(43) Pub. Date: Jul. 19, 2012

(54) PHOTOVOLTAIC MODULE HAVING A FRONT SUPPORT STRUCTURE FOR REDIRECTING INCIDENT LIGHT ONTO A PHOTOVOLTAIC CELL

(76) Inventor: Allan Ward, III, Perrysburg, OH (US)

(21) Appl. No.: 13/008,555

(22) Filed: Jan. 18, 2011

(51) Int. Cl. H01L 31/052; H01L 31/18

(52) U.S. Cl. 136/246; 438/65; 257/E31.127

(57) ABSTRACT

Embodiments of a method and apparatus are described which provide a photovoltaic module in which light is diverted away from inactive areas of the photovoltaic module to active areas which generate electrical charges. A front support structure of a module is configured to redirect incident light to the active areas.

### FIELD OF THE INVENTION

Embodiments of the invention relate to the field of photovoltaic (PV) power generation systems, and more particularly to a photovoltaic module and a manufacturing method thereof

### BACKGROUND OF THE INVENTION

A photovoltaic (PV) module or solar module, also known as a solar panel, is a device that converts the energy of sunlight directly into electricity by the photovoltaic effect. A PV module includes a plurality of PV cells, also known as solar cells, for example, crystalline silicon cells or thin-film cells formed of various materials. A PV module may have hundreds of series connected PV cells and produce hundreds of Watts of electricity.

In a thin-film PV module, the thin-film cell includes sequential layers of various materials formed between a front support and a back support. The layers can include, for example, a transparent conducting oxide (TCO) layer, an active material layer and a conductive layer. The front and back supports can be made of a transparent material, such as, glass, to allow light to pass through to the active material layer of the cell. The conductive layer can be a metal layer that acts as an electrode. The active material layer is formed of one or more layers of semiconductor material such as amorphous silicon (a-Si), cadmium telluride (CdTe), copper indium gallium diselenide (CIGS) or other photoconversion materials.

A scribing process is typically used to produce a thin-film PV module containing a plurality of series connected PV cells. FIGS. 1A through 1G depict one example of a manufacturing production process for making a thin-film PV module having a CdTe based active material layer. As shown in FIG. 1A, the production process begins with preparing a front support 110 such as a soda-lime float glass superstrate. Next, in FIG. 1B, a TCO layer 120 such as SnO₂ of approximately 0.2-0.5 μm thick is uniformly deposited on the front support 110. As shown in FIG. 1C, portions of the TCO layer 120 are removed by a scribing process to pattern the TCO layer 120 on the front support 110 into isolated stripes of front electrodes separated by scribe lines 121. The scribe lines 121 may each be tens to hundreds of μm wide and are spaced about every 1 cm. Next, in FIG. 1D, an active material layer 130 is deposited on the TCO layer 120. The active material layer 130 may comprise a CdS layer approximately 10-250 nm thick deposited on the TCO layer 120 and a CdTe layer approximately 2-8 μm thick deposited on the CdS layer. A p-n junction is formed near the interface of the n-type CdS layer and the p-type CdTe layer. As shown in FIG. 1E, further scribing occurs along scribe lines 131 which are laterally shifted from scribe lines 121 to remove and isolate the active material layer 130 of each PV cell 150. Next, in FIG. 1F, a conductive layer 140 is deposited on the active material layer 130 and within the scribe lines 131. Finally, portions of the conductive layer 140 and active material layer 130 are removed along scribe lines 141 which are laterally shifted with respect to scribe lines 131 to isolate rear electrodes, as shown in FIG. 1G. This latter scribing step creates a plurality of PV cells 150 connected in series in the module 100. Each PV cell 150 comprises active photoconversion areas formed by the TCO layer 120, active material layer 130 and the conductive layer 140. As shown in FIG. 1H, a back support 180 is then applied along with an electrical insulator 170 edge seal which encapsulates and seals the peripheral edge of the module 100 to create a suitable tracking distance for reducing the risk of electrical shock. Electrical charges are generated as photons pass through the front support 110 and are absorbed by the active material layer 130 generating electron-hole pairs that are separated by the electric field at the p-n junction of the PV cell 150.

Scribing is an important step in the production of the PV cells 150. The first scribe lines 121 form isolated stripes of front electrodes in the TCO layer 120. The second scribe lines 131 define the PV cells 150 as well as the interconnect path for electrons to flow from one PV cell 150 to the next. The third scribe lines 141 pattern rear electrodes to form the series connected PV cells 150. The scribe lines can be formed by any suitable means including masking and etching, mechanical scribing or laser scribing.

A conventional PV module typically absorbs only 70% of incoming light in part because certain areas of the module do not participate in the conversion of photons to electrical power. The scribe lines 121, 131 and 141 form inactive areas 160 between adjacent PV cells 150 that do not participate in the photovoltaic conversion process as a result of removing portions of the different layers 120, 130 and 140 of the PV cells 150. Photons striking the front support 110 above an inactive area 160 of the photovoltaic module 100 are not converted to electrical energy because they are not absorbed by the active material layer 130 of a photovoltaic cell 150 in module 100. Given that a PV cell 150 can be less than 10 mm wide, an inactive area 160 of tens to hundreds of μm wide can significantly affect the photoconversion efficiency of the module 100.

Although one example of a process for forming a thin-film PV module 100 is depicted in FIGS. 1A through 1H, it will be appreciated that a PV module having multiple PV cells can be produced by other techniques providing the depositing and scribing of various material layers. However, the scribing process still leaves inactive areas within a module where no photoconversion can occur.

FIG. 2B depicts an example of another PV module 200 having multiple crystalline silicon PV cells 250. In this example, metal conductors 210 are used to electrically connect adjacent PV cells 250 in series. The PV cells 250 are crystalline silicon cells provided between a glass substrate layer 220 and a resin or glass layer 230 as shown in FIG. 2A. The metal conductors 210 form inactive areas 260 that do not participate in the photoconversion process. Other inactive areas 260 may also be present within module 200. Photons striking the module 200 above the inactive areas 260 as well as at the structural edges 240 of the PV module 200 are not converted to electrical energy.

The scribe lines, electrical insulators, metal conductors, structural edges and other portions of a photovoltaic module which do not participate in the conversion of photons to electrical power decrease the overall efficiency of the photovoltaic module. Accordingly, there is a need for an improved photovoltaic module which mitigates against the effects of such areas and which provide a module with higher efficiency in converting photons to electrical energy.

### BRIEF DESCRIPTION OF THE DRAWINGS

FIGS. 1A through 1H illustrate an example of a photovoltaic module manufacturing process;

FIG. 2A is a cross-sectional view of an example of another photovoltaic module;

FIG. 2B is a perspective view of the photovoltaic module of FIG. 2A;

FIG. 3 is a perspective view of an example of a photovoltaic module in accordance with a disclosed embodiment;

FIG. 4 is a cross-sectional view of the photovoltaic module of FIG. 3;

FIG. 5 is a cross-sectional view of an example of another photovoltaic module in accordance with a disclosed embodiment;

FIG. 6A is a cross-sectional view of an example of another photovoltaic module in accordance with a disclosed embodiment;

FIG. 6B is a perspective view of the photovoltaic module of FIG. 6A;

FIG. 7A is a cross-sectional view of an example of a photovoltaic module in accordance with another disclosed embodiment;

FIG. 7B is a top view of an example of a photovoltaic module in accordance with a disclosed embodiment;

FIG. 7C is a cross-sectional view of an example of another photovoltaic module in accordance with a disclosed embodiment;

FIG. 8A is a perspective view of an example of a photovoltaic module in accordance with a disclosed embodiment; and

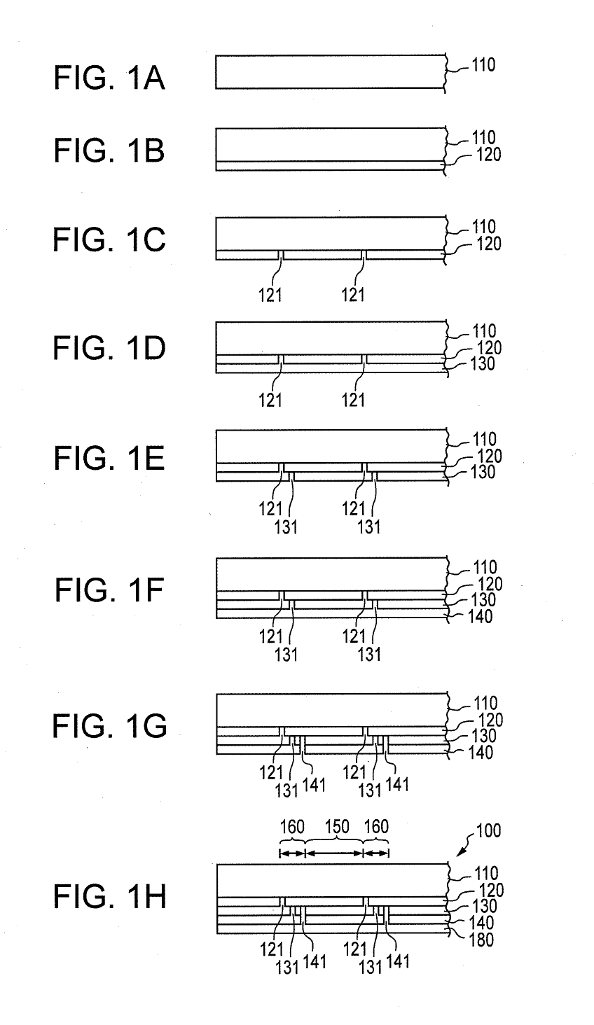

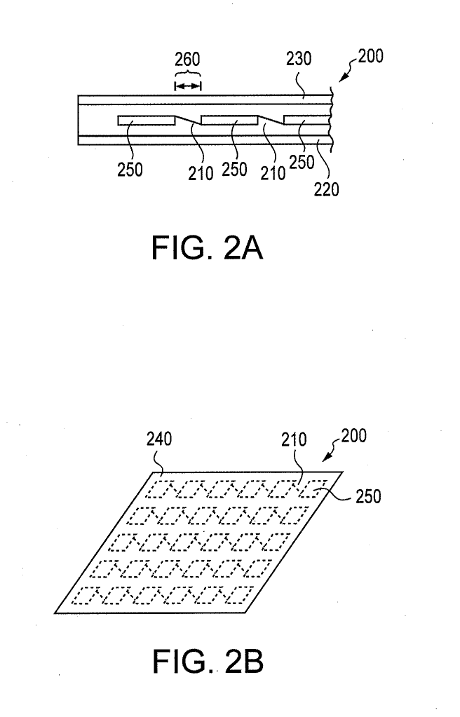

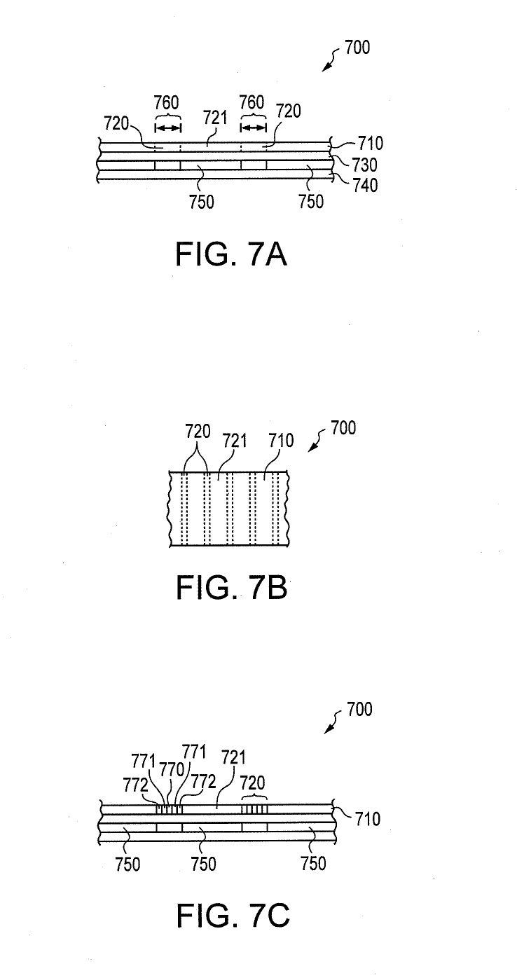

FIG. 7B is a top view of an example of a photovoltaic module in accordance with a disclosed embodiment.

### DETAILED DESCRIPTION OF THE INVENTION

In the following detailed description, reference is made to the accompanying drawings which form a part hereof, and in which is shown by way of illustration specific embodiments that may be practiced. It should be understood that like reference numbers represent like elements throughout the drawings. These embodiments are described in sufficient detail to enable those skilled in the art to make and use them, and it is to be understood that structural, material, electrical, and procedural changes may be made to the specific embodiments disclosed, only some of which are discussed in detail below.

Described herein are embodiments of a photovoltaic module which better directs photons that would otherwise be directed to inactive areas of the module and redirects them toward the active areas, without increasing the surface area of the photovoltaic cells. One embodiment of the photovoltaic module has a front support structure with a shaped top surface that acts as a light deflector to redirect incident photons away from inactive areas and towards active areas of a module. Another embodiment of the photovoltaic module has a front support structure with an index of refraction that changes over the inactive areas of the module causing photons to be redirected from inactive areas to the active areas within the module. Also, described herein are methods of manufacturing the various embodiments of the photovoltaic module.

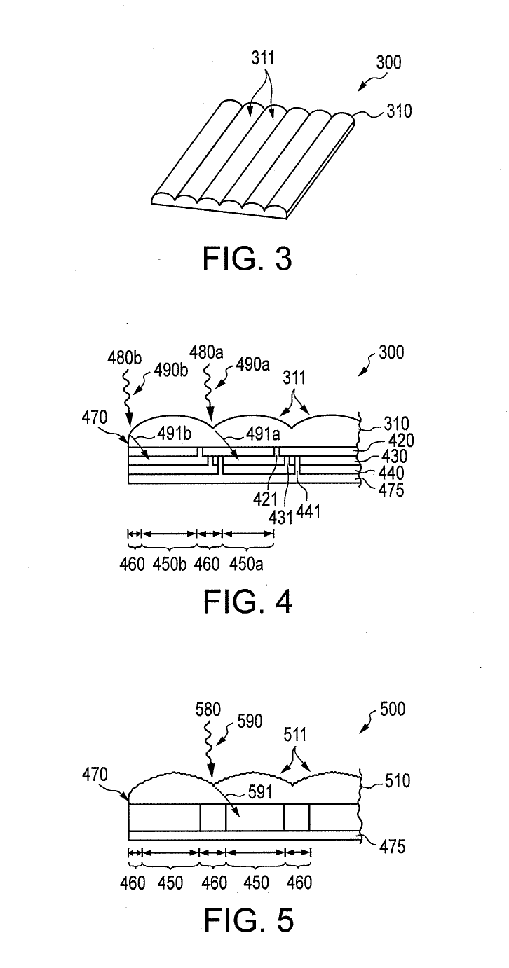

A first example embodiment of a photovoltaic module 300 is depicted in FIG. 3. Photovoltaic module 300 is an integrated structure having a shaped front support structure 310. The front support structure 310 forms a plurality of lenses 311. Each lens 311 preferably has a top view surface which corresponds to but is longer than a top view shape of an underlying photovoltaic cell such that the area encompassed by the lens 311 corresponds to the area of the photovoltaic cell. For example, in this example embodiment, each lens 311 covers a photovoltaic cell and at least a portion of the inactive areas outside of the respective photovoltaic cell. FIG. 3 shows only a subset of the lenses 311 of the PV module 300; however it should be understood that module 300 can include, for example, hundreds of curved lenses corresponding to the photovoltaic cells in module 300. Other passive and active components such as electrodes and terminals associated with module 300 are not shown in FIG. 3. It should be noted that PV module 300 which is illustrated is not intended to be considered a limitation on the configuration or types of PV modules to which the present invention may be applied.

FIG. 4 depicts a cross-sectional view of a portion of photovoltaic module 300 in accordance with the first embodiment. Module 300 has a plurality of thin-film PV cells 450 which are electrically isolated and interconnected using a scribing process. Each PV cell 450 is made up of multiple layers of deposited semiconductor materials and scribed to form interconnected photovoltaic cells 450. The layers can be deposited sequentially on front support structure 310 using a physical vapor deposition process, such as evaporation or sputter deposition, a chemical vapor deposition process, or other suitable process. For example, FIG. 4 shows a TCO layer 420 deposited on the front support structure 310, an active material layer 430 deposited on the TCO layer 420, a conductive layer 440 deposited on the active material layer 430 and a back support 475 added on the conductive layer 440. The deposition of the materials or the consecutive annealing or both occur at elevated temperatures typically in range of 300-600° C., but could be higher or lower for short amounts of time.

TCO layer 420 can be doped tin oxide, cadmium tin oxide, tin oxide, indium oxide, zinc oxide or other transparent conductive oxide or combination thereof. Active material layer 430 is preferably made up of at least one semiconductor window layer and at least one semiconductor absorber layer. Absorber layer may generate photo carriers upon absorption of solar radiation and can be made of amorphous silicon (a-Si), copper indium gallium diselenide (CIGS), cadmium telluride (CdTe) or any other suitable light absorbing material. Window layer can mitigate the internal loss of photo carriers (e.g., electrons and holes) in module 300. Window layer is a semiconductor material, such as cadium sulfide (CdS), zinc sulfide (ZnS), cadium zinc sulfide (CdZnS), zinc magnesium oxide (ZnMgO) or any other suitable photovoltaic semiconductor material. In an example embodiment, p-n junctions are formed in active material layer 430 using a cadmium telluride (CdTe) layer as the light absorbing material and a cadium sulfide (CdS) layer as the window layer.

After each layer 420, 430 and 440 is deposited, portions of the respective layer are removed forming scribe lines 421, 431 and 441, as shown in FIG. 4. The photovoltaic cells 450 represent the active areas of the photovoltaic module 300 where photons are converted to electrical charges. Scribe lines 421, 431 and 441, which are located between adjacent photovoltaic cells 450, form inactive areas 460 that do not participate in the photoconversion process.

It will be appreciated that other material layers such as one or more buffer layers may be deposited between the TCO layer 420 and the active material layer 430. The buffer layer can be tin oxide, zinc tin oxide, zinc magnesium oxide, zinc sulfur oxide or other transparent conductive oxide or a combination thereof. Preferably, the buffer layer is made from a material less conductive than the TCO layer 420. Also, one or more barrier layers may be deposited between the front support structure 310 and the TCO layer 420. The barrier layer can be silicon oxide, silicon aluminum oxide, tin oxide, or other suitable material or a combination thereof. Moreover, multiple TCO layers 420 may be deposited between the front 310 and back 475 support structures.

In addition, each of the material layers (e.g., 420, 430, 440) can include one or more layers or films, one or more different types of materials and/or same materials with differing compositions. The active material layer 430 and the optional buffer and barrier layers of photovoltaic cell 450 can be formed by any suitable combination of group III to V elements listed in the periodic table subject to lattice constant and band gap requirements, wherein the group III includes boron (B), aluminum (Al), gallium (Ga), indium (In), and thallium (T). The group IV elements include carbon (C), silicon (Si), germanium (Ge), and tin (Sn). The group V elements include nitrogen (N), phosphorous (P), arsenic (As), antimony (Sb), and bismuth (Bi). Other materials may be optionally included in the photovoltaic cell or module beyond what is mentioned to further improve performance such as AR coatings, color suppression layers, among others.

Front support structure 310 is made of a light transmissive insulative material that is transparent or translucent to light, such as soda lime glass, low Fe glass, solar float glass or other suitable glass. The conductive layer 440 can be made of molybdenum, aluminum, copper, or any other high conductive materials. The back support 475, which can be made of tempered glass, provides structural support and protects the photovoltaic cells 450 from environmental hazards. It will also be appreciated that the various material layers may be sequentially deposited and scribed in reverse order starting from the back support 475.

Front support structure 310 of module 300 has lenses 311 that act as light deflectors to redirect photons 480a-b to the photovoltaic cells 450 of module 300. The front support structure 310 is shaped or molded such that photons 480a-b that would otherwise be directed to inactive areas 460 are redirected toward the active areas of PV cells 450. For example, photons 480a striking the lens 311 above an inactive area 460 with an initial trajectory of 490a, as shown in FIG. 4, would be redirected to the photovoltaic cell 450a via trajectory 491a for photoconversion. In another example, photons 480b striking the lens 311 above the edge 470 with an initial trajectory of 490b would be directed to the photovoltaic cell 450b via trajectory 491b. Thus, module 300 is able to absorb more photons using the shaped front support structure 310. The output power of the module 300 with the shaped front support structure 310 can be increased by up to 5% compared to conventional flat front surface photovoltaic module.

Photovoltaic module 300 can be formed with the lenses 311 as an integrated structure. It will be appreciated by those skilled in the art that the lenses 311 can formed as classical plano-convex lenses as shown in FIGS. 3 and 4. Each PV cell 450 or a group of PV cells 450 can be covered by a lens 311. The lens 311 covering a PV cell 450 extends from the center of an inactive area 460 on one side of the cell 450 to the center of the inactive area 460 on the other side of the cell 450 or to the edge of the PV module 300, as depicted in FIG. 4. In this manner, a plurality of lenses 311 can cover the entire width and length of the module 300. FIG. 3 shows only a subset of the lenses 311 of the PV module 300; however it should be understood that module 300 can include, for example, hundreds of lenses corresponding to the photovoltaic cells in module 300.

Alternatively, the front support structure 510 of module 500 can have a plurality of Fresnel lenses 511 as shown in FIG. 5. For simplicity, the various layers of photovoltaic cell 450 are not shown. The cell 450 is protected on the bottom by the back support 475. Photons 580 striking the Fresnel lens 511 of front support structure 510 with an initial trajectory of 590a as shown in FIG. 5 would be redirected away from the inactive area 460 toward the PV cell 450 via trajectory 591a. It will be appreciated that other lens shapes can be used on a front support structure to redirect photons from an inactive area to an active area of a photovoltaic cell.

The shaped front support structures 310 and 510 can be created in float glass using a glass milling technology such as, for example, a computer numerical control (CNC) glass milling machine, or any other type of milling machine, lasers or water jets. For non-float glass, a glass press can be used to stamp the desired shape into heated glass using a mold. Another method of fabricating the shaped front support structures 310 and 510 includes bonding of a prefabricated glass or polymeric film that has been shaped into the desired front support structure onto a glass or other suitable surface. Still another method of fabricating the shaped front support structures 310 and 510 involves making an injection molding of a polymeric material into the desired front support structure.

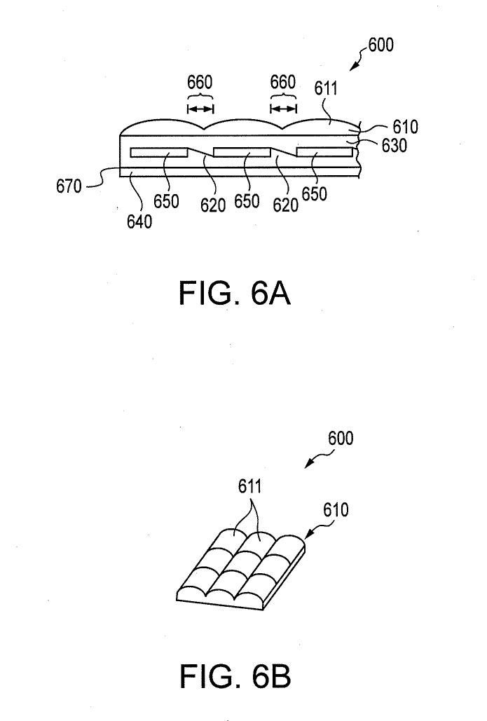

FIGS. 6A and 6B depict another example of an embodiment of a photovoltaic module 600. Photovoltaic module 600, a portion of which is shown in FIGS. 6A and 6B, is an integrated structure having a shaped front support structure 610. The front support structure 610 has an array of lenses 611 for redirecting photons to photovoltaic cells. Each lens 611 preferably has a top view surface which corresponds to but is longer than a top view shape of an underlying photovoltaic cell such that the area encompassed by the lens 611 corresponds to the area of the photovoltaic cell. In this example embodiment, each lens 611 covers a photovoltaic cell and at least a portion of the inactive areas outside of the respective photovoltaic cell. FIG. 6B shows only a subset of the lenses 611 of the PV module 600; however it should be understood that module 600 can include, for example, hundreds of lenses corresponding to the photovoltaic cells in module 600.

FIG. 6A is a cross-sectional view of PV module 600. PV module 600 has an array of crystalline silicon (also called wafer silicon) PV cells 650. It should be noted that the FIGS. 6A and 6B example of a PV module 600 is not intended to be considered a limitation on the types of photovoltaic modules to which the present invention may be applied, but rather a convenient representation for the following description.

Each PV cell 650 is formed in a silicon wafer doped with, for example, boron and phosphorous to form a p-n junction. Metal contacts (not shown) made of, for example, copper or silver or other metal, are deposited on the top and bottom surfaces of cell 650 and metal conductor strips 620 made of preferably copper are used to interconnect adjacent cells 650. The photovoltaic cells 650 are typically encapsulated with a protective material, for example, an ethylene vinyl acetate 630, which is located between a backsheet 640 and a front support structure 610. The backsheet 640 can be made of glass, mylar, tedlar or any other suitable backing material. The front support structure 610 is preferably glass but can also be plastic or any other suitable material. Other materials may be optionally included in the production process beyond what is mentioned to further improve performance such as anti-reflective coatings, color suppression layers, among others.

The crystalline silicon PV cells 650 represent the active areas of the photovoltaic module 600 where photons are absorbed and converted to electrical charges. The metal conductor strips 620 located between adjacent cells 650 and the edge 670 of the module 600 are inactive areas 660 that do not participate in the photoconversion process.

Like the lens 311 of front support structure 310 in FIG. 4, the lens 611 of front support structure 610 can be a classical plano-convex lens 611 as shown in FIG. 6A. The front support structure 610 is shaped or molded such that incident photons that would otherwise be directed to the inactive areas 660 are redirected toward the PV cells 650. It will be appreciated that front support structure 610 can also be formed with a plurality of Fresnel lenses like the one shown in FIG. 5, or any other curved lens that can redirect photons striking the front support structure 610 toward the active areas of photovoltaic cells 650. In addition, the front support structure 610 can be manufactured using the same techniques discussed above with reference to FIG. 4 for manufacturing the front support structure 310.

FIG. 7A depicts a cross-sectional view of an example of a photovoltaic module 700 in accordance with another embodiment. Photovoltaic module 700 includes a plurality of interconnected photovoltaic cells 750. Photovoltaic module 700 may include multiple thin-film photovoltaic cells such as shown in the examples of FIGS. 4 and 5 or multiple crystalline silicon photovoltaic cells such as shown in the example of FIG. 6A, or any other suitable photovoltaic cells which are arranged in module 700 in a manner such that there are areas that do not participate in the photoconversion process. Various optional material layers 730 and 740 such as a barrier layer, as described above in connection with FIG. 4, or an ethylene vinyl acetate layer, as described in connection with FIG. 6A, can be added above and below the photovoltaic cell 750. Regardless of the type of technology used in the photovoltaic cells 750, the module 700 has inactive areas 760 formed by the use of scribes, metal conductor strips, electrical insulators, and/or other components that do not convert photons to electrical charges.

Unlike the shaped front support structures 310, 510 and 610 described above in connection with FIGS. 4, 5 and 6A, the front support structure 710 is not shaped or curved. Instead, the front support structure 710 has a refractive index in region 720 that is different from the refractive index of the rest of the front support structure 710. The change in refraction index causes incident light striking region 720 above the inactive area 760 to bend and be redirected to the photovoltaic cells 750. Each region 721 preferably follows the shape of a photovoltaic cell such that the area of the region 721 corresponds to the area of the photovoltaic cell 750. Each region 720 preferably follows the shape of the underlying inactive area 760 of module 700. The output power of the module 700 can be increased by up to 5% compared to a conventional photovoltaic module by capturing a wider angle of incidence through engineering a change in the index of refraction of the front support structure 710 above the inactive areas 760.

FIG. 7B is a top-level view of module 700. The front support structure 710 is made of light transmissive insulative material that is transparent or translucent to light, such as soda lime glass, low Fe glass, solar float glass or other suitable glass. The front support structure 710 can be made using a glass milling technology such as, for example, a computer numerical control (CNC) glass milling machine, or any other type of milling machine, lasers or water jets.

In this embodiment, the front support structure 710 is a glass structure having an index of refraction of approximately 1.52. The front support structure 710 is doped with a metallic element such as zinc, magnesium or a suitable combination thereof in regions 720 of module 700. The doping element added to regions. 720 cause regions 720 to have a lower index of refraction compared to the regions 721 above the photovoltaic cells 750 so that photons striking region 720 will bend toward region 721 to reach a photovoltaic cell 750. The doping elements can be added to front support structure 710 using photolithographic or etching methods familiar to the semiconductor industry.

Alternatively, it will be appreciated that the front support structure 710 can be manufactured with a step refraction index in region 720 by doping region 720 with doping elements having different indices of refraction. To form a front support structure 710 with a step refraction index as shown in FIG. 7C, subregion 772 of region 720 is doped with a doping element having an index of refraction that is lower than the index of refraction for region 721. Subregion 771 is doped with a doping element having an index of refraction that is lower than the index of refraction for subregion 772. Subregion 770 is doped with a doping element having an index of refraction that is lower than the index of refraction for subregion 771. As such, when incident light strikes front support structure 710 at region 720, the light will continuously bend as it travels through the structure 710 toward a photovoltaic cell 750. It will be appreciated that the front support structure 710 can alternatively be manufactured with a graded refraction index in region 720 where the refraction index is lowest in the center of region 720.

Still other alternative methods of manufacturing front support structure 710 include a holographic laser pattern that is added to regions 720 to produce, for example, a uniform refractive index, a step refractive index or a graded refractive index in regions 720 above the inactive areas 760 of module 700. Stoichiometric changes such as the ion stuffing method and other methods familiar to the semiconductor industry can also be used to manufacture the front support structure 710 with a suitable change in refraction index.

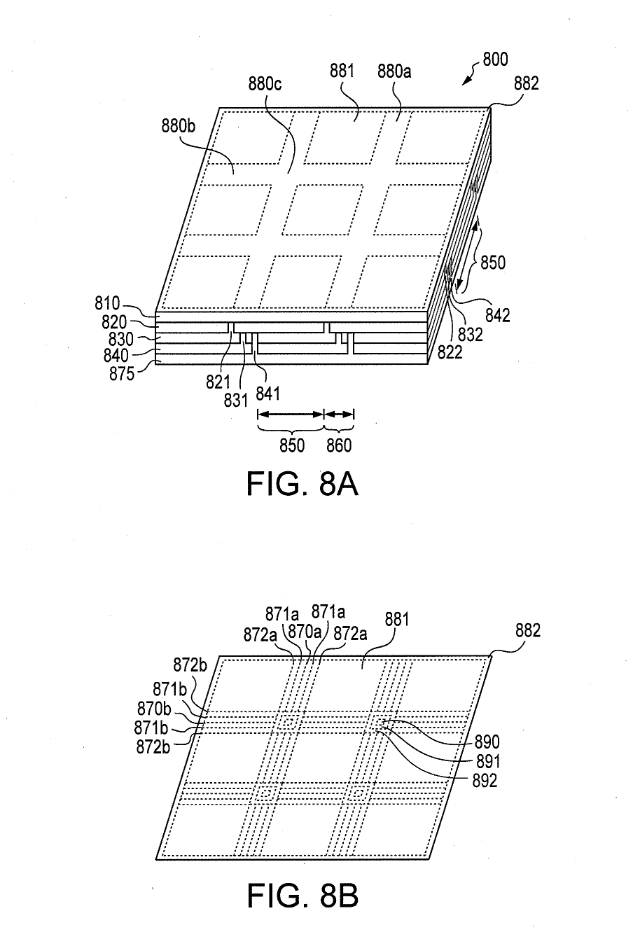

FIG. 8A is a perspective view of another example thin-film photovoltaic module 800 having an array of photovoltaic cells 850. Module 800 has a plurality of PV cells 850 which are electrically isolated and interconnected using a scribing process. Each PV cell 850 is made up of multiple layers of semiconductor materials deposited on a front support structure 810 and scribed to form interconnected photovoltaic cells 850. FIG. 8 shows a TCO layer 820 is deposited on the front support structure 810, an active material layer 830 is deposited on the TCO layer 820, a conductive layer 840 is deposited on the active material layer 830 and a back support 875 is added on the conductive layer 840. The semiconductor materials used for each layer 820, 830 and 840 can be the same materials described above with respect to the example photovoltaic module 300 of FIG. 4. After each layer 820, 830 and 840 is deposited, portions of the respective layer are removed forming scribe lines 821, 831 and 841 in the vertical direction and scribe lines 822, 832 and 842 in the horizontal direction to form an array of photovoltaic cells 850, as shown in FIG. 4. The photovoltaic cells 850 represent the active areas of the photovoltaic module 800 where photons are converted to electrical energy. Scribe lines 821, 831 and 841 and scribe lines 822, 832 and 842, which are located between adjacent photovoltaic cells 850, form inactive areas 860 that do not participate in the photoconversion process.

Module 800 has region 880 located above inactive areas 860 and region 882 located above the inactive edge portion of module 800 that do not convert photons to electrical charges. The front support structure 810 of module 800 is doped with a metallic element such as zinc, magnesium, or a suitable combination thereof in regions 880 and 882, which causes region 880 and 882 to have a lower index of refraction compared to the regions 881 above the photovoltaic cells 850. Each region 811 preferably follows the shape of an underlying photovoltaic cell 850 such that the area of the region 811 corresponds to the area of the underlying photovoltaic cell 850. Region 880 preferably follows the shape of an underlying inactive area 860 of module 800. Incident photons striking region 880 will bend toward region 881 to reach a photovoltaic cell 850.

Alternatively, it will be appreciated that the front support structure 810 can be manufactured with a step refraction index in region 880 by doping region 880 with doping elements having different indices of refraction. As shown in FIG. 8B, region 880 can have vertical 880a and horizontal 880b stripped regions and a region 880c where the vertical 880a and horizontal 880b regions intersect. Vertical 880a striped region has parallel striped subregions 870a, 871a and 872a. Similarly, horizontal 880b striped region has parallel striped subregions 870b, 871b and 872b. The vertical 880a and horizontal 880b stripped regions can be doped in similar fashion to region 720 in FIG. 7C. For example, subregions 872a, 872b and 892 are doped with a doping element having an index of refraction that is lower than the index of refraction for region 881. Alternatively, subregions 872a, 872b and 892 can be doped with doping elements having different indices of refraction as long as their indices of refraction are lower than the index of refraction for region 881. Subregions 871a, 871b and 891 are doped with a doping element having an index of refraction that is lower than the index of refraction for respective subregions 872a, 872b and 892. Subregions 870a, 870b and 890 are doped with a doping element having an index of refraction that is lower than the index of refraction for respective subregions 871a, 871b and 891. As such, when incident light strikes front support structure 810 at regions 880a, 880b and 880c, the light will continuously bend as it travels through the structure 810 toward a photovoltaic cell 850. It will be appreciated that the front support structure 810 can alternatively be manufactured with a graded refraction index in region 880 where the refraction index is lowest in the center of respective regions 880a, 880b and 880c. The doping element can be added to any other area of the front support structure 810 to divert photons away from any other inactive area in module 800.

While disclosed embodiments have been described in detail, it should be readily understood that the invention is not limited to the disclosed embodiments. Rather the disclosed embodiments can be modified to incorporate any number of variations, alterations, substitutions or equivalent arrangements not heretofore described.

What is claimed as new and desired to be protected by Letters Patent of the United States is:

1. A photovoltaic module comprising:
a plurality of electrically interconnected and laterally spaced photovoltaic cells provided between a front support structure and a back support structure,
said photovoltaic cells providing active photoconversion areas and areas outside of said photovoltaic cells being inactive areas where no photoconversion occurs,
said front support structure being configured to divert light incident on the front support structure away from the inactive areas and toward said active areas.

2. The photovoltaic module of claim 1, wherein photovoltaic cells are defined by scribe lines, which form at least part of the inactive areas.

3. The photovoltaic module of claim 1, wherein the front support structure comprises a plurality of curved lenses, each of said curved lenses covering at least one photovoltaic cell and at least a portion of said areas outside of said at least one photovoltaic cell.

4. The photovoltaic module of claim 3, wherein said curved lens has a plano-convex lens shape.

5. The photovoltaic module of claim 2, wherein the front support structure comprises a plurality of Fresnel lenses, each of said Fresnel lenses covering at least one photovoltaic cell and at least a portion of said areas outside of said at least one photovoltaic cell.

6. The photovoltaic module of claim 1, wherein a first region of the front support structure above the inactive areas has a first index of refraction and a second region of the front support structure above said active photoconversion areas of said photovoltaic cells has a second index of refraction that is different from the first index of refraction.

7. The photovoltaic module of claim 6, wherein the first index of refraction is lower than the second index of refraction.

8. The photovoltaic module of claim 7, wherein the first region is comprised of a plurality of subregions which provide a stepped refractive index for diverting light away from said inactive areas and towards said active areas.

9. The photovoltaic module of claim 7, wherein the first region is comprised of a plurality of subregions which provide a graded refractive index for diverting light away from said inactive areas and towards said active areas.

10. The photovoltaic module of claim 6, further comprising a holographic laser pattern provided in said first region for producing the first index of refraction.

11. The photovoltaic module of claim 1, wherein photovoltaic cells are interconnected using metal conductors, said metal conductors being located in said inactive areas.

12. The photovoltaic module of claim 1, further comprising an edge portion of said module, said edge portion forming at least part of the inactive areas.

13. The photovoltaic module of claim 3, wherein the module comprises an array of photovoltaic cells and a corresponding array of curved lenses.

14. The photovoltaic module of claim 13, wherein each lens has a top view shape which corresponds to a top view shape of an underlying photovoltaic cell.

15. The photovoltaic module of claim 14, wherein said top view shape of said lens is longer than said top view shape of said underlying photovoltaic cell.

16. The photovoltaic module of claim 6, wherein said second region follows the shape of an underlying photovoltaic cell.

17. The photovoltaic module of claim 16, wherein said first region follows the shape of an underlying inactive area.

18. A method of manufacturing a photovoltaic module comprising:
fabricating a plurality of interconnected photovoltaic cells, each having an active area for photoconversion, said fabrication producing inactive areas outside of said photovoltaic cells where no photoconversion occurs; and
providing a front support structure over said plurality of photovoltaic cells, said front support structure configured such that light contacting the front support structure above an inactive area is directed towards a photovoltaic cell.

19. The method of claim 18, wherein the inactive area includes a structure which interconnects photovoltaic cells of said plurality of photovoltaic cells.

20. The method of claim 19, wherein said fabricated plurality of photovoltaic cells have scribe lines between photovoltaic cells, the scribe lines forming a portion of said inactive areas.

21. The method of claim 18, further comprising providing said front support structure with a plurality of curved lenses, each of said curved lenses covering at least one photovoltaic cell and at least a portion of said inactive areas outside of said at least one photovoltaic cell.

22. The method of claim 18, further comprising providing said front support structure with a plurality of Fresnel lenses, each of said Fresnel lenses covering at least one photovoltaic cell and at least a portion of said inactive areas outside of said at least one photovoltaic cell.

23. The method of claim 18, further comprising electrically connecting pairs of photovoltaic cells using metal conductor strips, said metal conductor strips being located in said inactive areas.

24. The method of claim 21, wherein each lens has a top view shape which corresponds to a top view shape of an underlying photovoltaic cell.

25. The method of claim 24, wherein said top view shape of said lens is longer than said top view shape of said underlying photovoltaic cell.

26. The method of claim 18, further comprising providing said front support structure with a first region above said inactive areas with a first index of refraction and a second region above said active areas with a second different index of refraction.

27. The method of claim 26, further comprising doping the first region of the front support structure such that the first index of refraction is lower than the second index of refraction.

28. The method of claim 27, further comprising forming the first region with a plurality of subregions which provide a stepped refractive index for diverting light away from said inactive areas and towards said active areas of said photovoltaic cells.

29. The method of claim 27, further comprising forming the first region with a plurality of subregions which provide a graded refractive index for diverting light away from said inactive areas and towards said active areas of said photovoltaic cells.

30. The method of claim 26, further comprising providing a holographic laser pattern in said first region for producing the first index of refraction.

31. The method of claim 26, wherein said second region follows the shape of an underlying photovoltaic cell.

32. The method of claim 31, wherein said first region follows the shape of an underlying inactive area.
